(19) United States
(12) Patent Application Publication
(10) Pub. No.: US 2004/0056667 A1
(43) Pub. Date: Mar. 25, 2004

(54) Level measuring instrument

(76) Inventors: Wolfram Lutke, Rosenheim (DE); Alexander Hardell, Rijswijk (DE); Roland Muller, Steinen (DE)

Correspondence Address: Felix J. D'Ambrosio, JONES, TULLAR & COOPER, P.C., P.O. Box 2266 Eads Station, Arlington, VA, 22202, US

(21) Appl. No.: 09/942,561

(22) Filed: Aug. 31, 2001

(30) Foreign Application Priority Data
Oct. 17, 2000 (DE) 100 51 297:6

(51) Int. Cl. G01R 27/04; G01R 27/32

(52) U.S. Cl. 324/644

(57) ABSTRACT

Level measuring instrument The invention specifies a level measuring instrument operating with microwaves which transmits highly focussed microwaves in the transmission direction during operation and has an antenna (9) with a low space requirement, having a microwave generator (13) for producing microwaves at frequencies of greater than 40 GHz, an antenna (9, 9a) which is powered by the microwave generator (13) and is used to transmit the microwaves in the direction of the filled product, an antenna (9, 9b) which is used to receive microwaves reflected at a filled product surface, and a reception and evaluation circuit (15) which ascertains a transit time for the microwaves and uses this to determine the present level.

### BACKGROUND OF INVENTION

The invention relates to a level measuring instrument operating with microwaves in order to measure a level of a filled product in a container having a microwave generator, an antenna which is powered by the microwave generator and is used to transmit the microwaves in the direction of the filled product, an antenna used to receive microwaves reflected at a filled product surface, and a reception and evaluation circuit which ascertains the transit time of the microwaves and uses this to determine the present level.

In level measurement, microwaves are transmitted to the surface of a filled product using an antenna, and echo waves reflected at the surface are received. An echo function representing the echo amplitudes as a function of the distance is formed and is used to determine the probable useful echo and the transit time thereof. The transit time is used to determine the distance between the filled product surface and the antenna.

Conventional level measuring instruments operating with microwaves currently use frequencies of a maximum of 24 GHz. This is equivalent to a wavelength of 12 mm.

In industrial measurement, dielectric rod antennas and horn antennas are regularly used for transmitting and/or receiving. Typically, use is made of a housing having a housing section which has the geometry of a short-circuited hollow waveguide. Inserted into the housing section having the hollow waveguide geometry is an exciter element which is used to transmit and/or receive microwaves through the housing section. Alternatively, instead of an exciter element, antennas having planar antenna structures can be used for transmitting and/or receiving [lacuna]. The European patent application registered on 9.7.99 and having the application number 99 11 7604.1 describes an antenna having a planar antenna structure which is suitable for level measurement. Such planar antennas are also described in the book ‘Einführung in die Theorie und Technik planarer Mikrowellenantennen in Mikrostreifenleitungstechnik’ [Introduction to the theory and technology of planar microwave antennas in microstrip line technology], Gregor Gronau, Verlagsbuchhandlung Nellissen-Wolff or in the periodical article ‘Impedance of radiation slot in the ground plane of a microstrip line’, IEEE Trans. Antennas Propagat., Vol. AP-30, pages 922-926, May 1982.

During transmission, the microwaves are generated by a remotely arranged microwave generator and are transported to a transmission and reception element by means of coaxial lines. In the antenna, the transmission and reception element is used to convert supplied line-conducted microwaves into microwaves which propagate in free space, and vice versa.

In the case of a horn antenna, a funnel-like section which broadens in the direction of the container and forms the horn adjoins the housing. In the case of the rod antenna, a rod made of a dielectric and pointing into the container is provided. The interior of the housing is usually virtually completely filled by an insert made of a dielectric. In the case of the horn antenna, the insert has a conical end pointing into the container. In the case of rod antennas, the rod-like antenna adjoins the insert.

Level measurement can be performed using a single antenna which is used both for transmitting and for receiving microwaves. Alternatively, it is possible to use one antenna for transmission and another antenna for reception of the microwaves reflected at the filled product surface.

To determine the level, it is possible to use any known methods which permit relatively short distances to be measured using reflected microwaves. The best known examples are pulsed radar and frequency modulated continuous wave radar (FMCW radar).

In the case of pulsed radar, short microwave transmitted pulses, called wave packets below, are transmitted cyclically, are reflected from the filled product surface and are received again after a distance-dependent transit time. The received signal amplitude as a function of time constitutes the echo function. Each value of this echo function corresponds to the amplitude of an echo reflected at a specific distance from the antenna.

In the FMCW method, a continuous microwave is transmitted and is cyclically subjected to linear frequency modulation, for example on the basis of a sawtooth function. The frequency difference between the frequency of the received echo signal and the instantaneous frequency of the transmitted signal at the instant of reception is therefore dependent on the transit time of the echo signal. The frequency difference between transmitted signal and received signal, which difference can be obtained by mixing the two signals and evaluating the Fourier spectrum of the mixed signal, thus corresponds to the distance between the reflecting surface and the antenna. In addition, the amplitudes of the spectral lines of the frequency spectrum obtained by Fourier transformation correspond to the echo amplitudes. This Fourier spectrum therefore constitutes the echo function in this case.

In conventional level measuring instruments, the problem arises that the microwaves are radiated not only in the transmission direction required. The antenna has a directional characteristic with a radiation lobe having an beam angle which is a measure of the width of scatter of the transmitted microwaves. Hence, it is not only microwaves which have taken the direct path to the filled product surface and back which are received, but also microwaves which have taken an indirect path, e.g. additional reflection at the container wall. Whereas the first microwaves mentioned form the useful echo, the latter microwaves form interference signals which are superimposed on the useful echo and may result in sometimes considerable measurement errors.

To improve the measurement accuracy and the reliability of these level measuring instruments, it is essential to reduce these interference signals as far as possible. This can be achieved by improving the directional characteristic of the antenna, for example. It is possible to reduce the beam angle of the radiation lobe by enlarging an aperture of the antenna. This course of action is restricted, however, since a larger aperture necessitates a larger antenna diameter, and the antenna usually needs to be inserted through a container opening at the place of measurement, e.g. into a tank.

In many applications, the space provided at the place of measurement for fitting the level measuring instrument is small. By way of example, container openings with nozzles and flanges arranged thereon are frequently provided which have a nominal width of 50 mm to 100 mm. This measurement represents an upper limit for the antenna diameter, the aperture.

### SUMMARY OF THE INVENTION

It is an object of the invention to specify a level measuring instrument operating with microwaves which transmits highly focussed microwaves in the transmission direction during operation and has an antenna with a low space requirement.

To achieve this, the invention comprises a level measuring instrument operating with microwaves in order to measure a level of a filled product in a container, having

a microwave generator,

for generating microwaves at frequencies of greater than 40 GHz,

an antenna which is powered by the microwave generator and is used to transmit the microwaves in the direction of the filled product,

an antenna which is used to receive microwaves reflected at a filled product surface, and

a reception and evaluation circuit

which ascertains a transit time for the microwaves and uses this to determine the present level.

In accordance with a preferred embodiment according of the invention, the microwave generator is arranged directly on the antenna.

In accordance with another preferred embodiment, the microwave generator is connected to the antenna by means of a passive waveguide.

In accordance with a further preferred embodiment, the passive waveguide is a hollow waveguide.

In accordance with still another embodiment of the invention, a product comprising an aperture of the antenna and a wavelength of the microwaves is much less than 500 mm².

In accordance with yet a further embodiment, the filled product is a bulk product, and the wavelength of the microwaves is in the order of magnitude of a mean particle size of the bulk product or is less than this particle size.

An advantage of the invention is that the microwaves [lacuna], on account of the very high frequency as compared with conventional level measuring instruments operating with microwaves, level measurements can also be carried out for bulk products forming a conical heap. The high frequency means that the wavelength of the microwaves is short. Tests have shown that level measurements are possible so long as the wavelength does not exceed the order of magnitude of the particle size.

The invention and other advantages are now explained in more detail with reference to the figures of the drawing, which show two exemplary embodiments; identical parts have been provided with the same reference symbols in the figures.

### BRIEF DESCRIPTION OF THE DRAWINGS

FIG. 1 shows, schematically, a measuring arrangement having a level measuring instrument operating with microwaves which is arranged on a nozzle on a container;

FIG. 2 shows a schematic illustration of an inventive level measuring instrument in which the microwave generator is arranged directly on the antenna;

FIG. 3 shows a plan view of a side of the board shown in FIG. 2 which points in the direction of transmission;

FIG. 4 shows a plan view of a side of the board shown in FIG. 2 which faces away from the direction of transmission;

FIG. 5 shows a schematic illustration of an inventive level measuring instrument in which the microwave generator is connected to the antenna by means of a passive waveguide;

FIG. 6 shows a block diagram of an inventive level measuring instrument in which an antenna is used for transmitting and for receiving microwaves; and

FIG. 7 shows a block diagram of an inventive level measuring instrument in which a first antenna is used for transmitting and a second antenna is used for receiving microwaves.

### DETAILED DESCRIPTION OF PREFERRED EMBODIMENTS

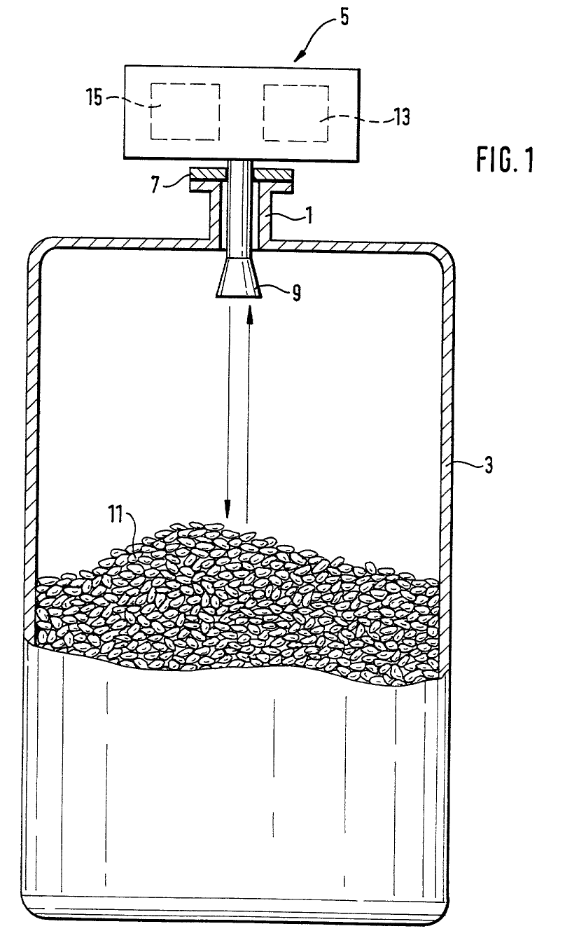

of the invention FIG. 1 shows, schematically, a measuring arrangement having a level measuring instrument 5 operating with microwaves which is arranged on a nozzle 1 on a container 3. The level measuring instrument 5 has a flange 7 used to mount it on an opposite flange provided on the nozzle 1. The level measuring instrument 5 comprises an antenna 9 which protrudes through the nozzle 1 into the container 3.

The container is filled with a filled product 11, whose level needs to be measured. In the chosen exemplary embodiment, the filled product 11 is a bulk product forming a conical heap.

The level measuring instrument 5 has a microwave generator 13 which, during operation, generates microwaves at frequencies of greater than 40 GHz. A suitable microwave generator 13 is, by way of example, a pulsed radar instrument designed using planar circuitry, an FMCW instrument designed using planar circuitry or a continuously oscillating microwave oscillator designed using planar circuitry, e.g. a Gunn oscillator.

The antenna 9 is powered by the microwave generator 13 and is used to transmit the microwaves in the direction of the filled product 11. In the exemplary embodiment shown, the antenna 9 is additionally used to receive microwaves reflected at a filled product surface.

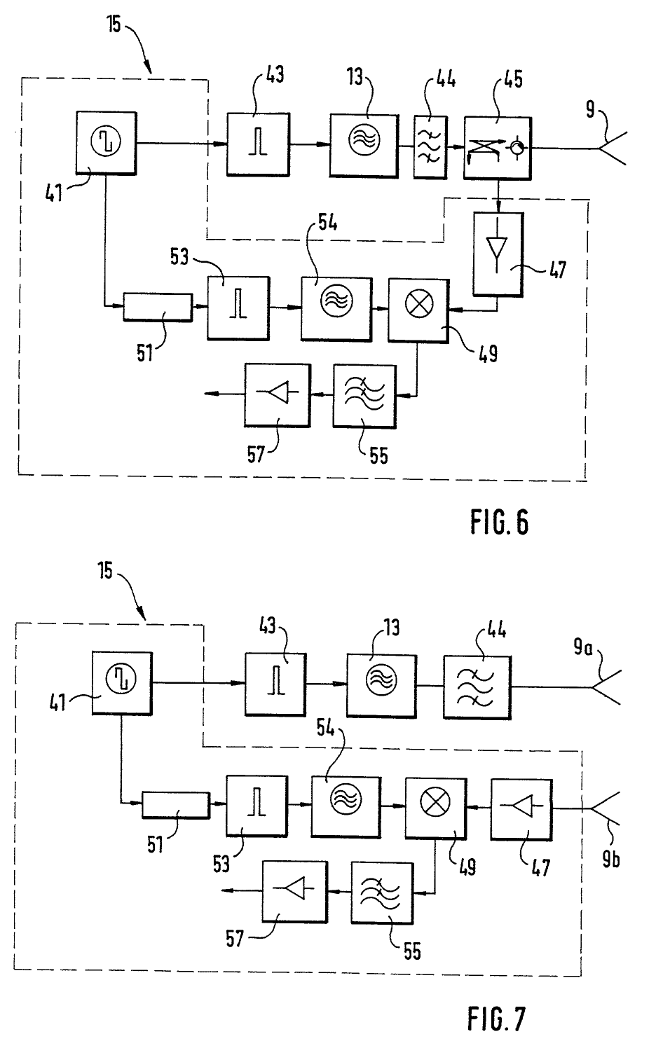

The microwaves received are supplied to a reception and evaluation circuit 15 which ascertains a transit time for the microwaves from the antenna 9 to the filled product surface and back, and uses this to determine the present level. An exemplary embodiment of such a reception and evaluation circuit 15 is shown in FIG. 6 and is explained in more detail below.

Instead of a single antenna 9 for transmitting and receiving, it is naturally also possible for two antennas to be provided, one of which is used for transmitting, and another antenna of which is used for receiving the reflected microwaves. An exemplary embodiment of a reception and evaluation circuit which can be used in conjunction with two antennas is shown in FIG. 7 and is explained in more detail below.

The transmitted frequencies are preferably situated within frequency bands permitted by the respective national safety authorities. Thus, in Europe and the USA, for example, frequencies of approximately 77 GHz are preferably to be used for pulsed radar instruments.

The higher the transmitted frequencies, the more directional is the radiation of microwaves for the same antenna aperture. However, high frequencies also require more complex electronic components for generating and processing them. Tests have shown that frequencies above 40 GHz permit reliable level measurement even in the case of very tall containers, for example with a height of 30 m, having small container openings, for example nozzles with diameters of 50 mm or 100 mm.

Preferably, a product comprising an antenna aperture D and a microwave wavelength λ is much less than 500 mm2. If this is the case, then the microwaves to be transmitted have a very good directional characteristic with a radiation lobe having a very small beam angle. The proportion of the microwaves which does not take a direct path to the filled product surface and from there back to the antenna 9 is then correspondingly very small. The small proportion of interference signals means that level measurement can be carried out in a very reliable fashion.

Preferably, when measuring the level of bulk products, the wavelength of the microwaves is in the order of magnitude of a mean particle size of the bulk product, or it is less than this particle size. The result of this is that, in graphical terms, the microwaves are reflected on individual particles of the bulk product and not at a sometimes greatly inclined conical heap surface.

In the case of this reflection on individual bulk product particles, the proportion of microwaves which is reflected back on a direct path in the direction of the antenna 9 is much greater than in the case of reflection at an inclined surface. In the latter case, the majority of the microwaves are reflected back at an angle which is dependent on the slope of the surface and then pass back to the antenna 9 only on an indirect path, if at all, for example as a result of reflection on a container wall.

One ultimate example of this which may be cited is the reflection of microwaves at a frequency of 77 GHz, which corresponds to a wavelength of approximately 4 mm, on plastic pellets, e.g. polyethylene with a mean particle size of 2 mm. The mean particle size is in the same order of magnitude as the microwave wavelength used, which means that reliable level measurement is still possible even though this filled product forms a conical heap in the container. Microwaves at frequencies above 40 GHz cannot, as previously customary in level measurement, be transported using cheap cables, e.g. the widely used relatively inexpensive coaxial lines. Today, specially made expensive coaxial lines are used for these high frequencies. These are very expensive in comparison with conventional coaxial lines, however.

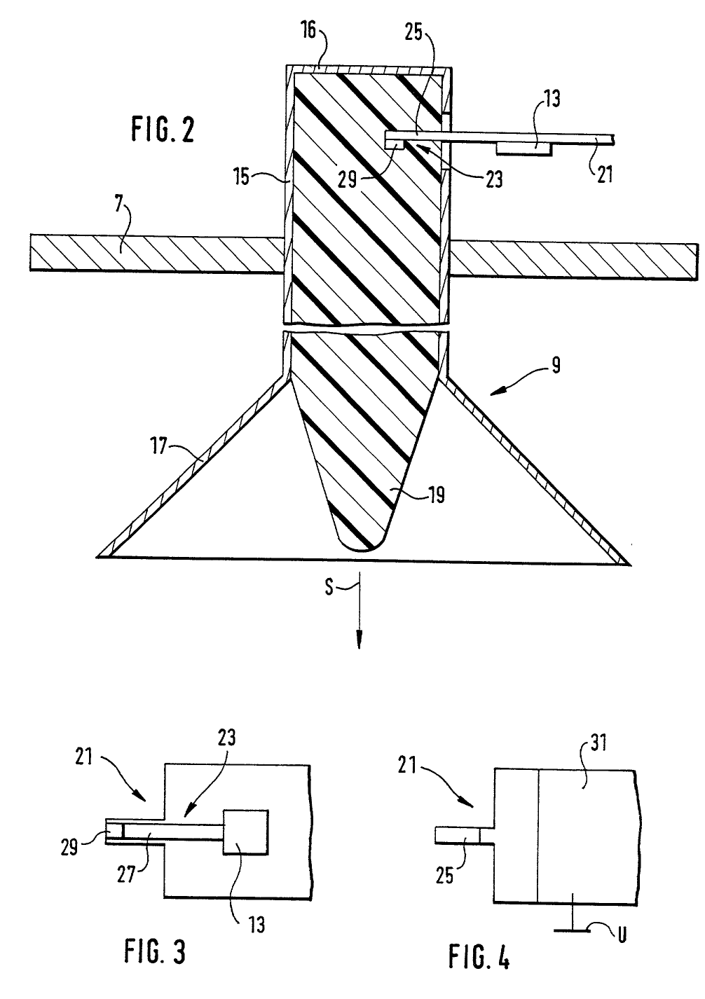

First, it is possible to produce the microwaves directly at the point at which they are radiated, that is to say directly on the antenna 9. Exemplary embodiments in which a microwave generator is arranged directly on an antenna are described in the German patent application having the file reference 100 23 497.6, with the registration date May 13, 2000. An exemplary embodiment based on this patent application is shown in FIG. 2 and is explained briefly below.

In the exemplary embodiment shown, the antenna 9 is a horn antenna and has a cylindrical hollow waveguide 15, short-circuited at the end on one side by a back wall 16, and a funnel-shaped horn 17 adjoining the hollow waveguide in the transmission direction. The transmission direction is symbolized in FIG. 2 by an arrow S. A diameter of the horn 17 increases in the transmission direction. The hollow waveguide 15 and the horn 17 are made of an electrically conductive material, e.g. a high-grade steel. Arranged in the interior of the hollow waveguide 15 is an insert 19 which is made of a dielectric, e.g. made of polytetrafluoroethylene (PTFE), is essentially cylindrical and fills the hollow waveguide 15. The insert 19 has a conical tip which projects into the horn 17.

The insert 19 serves primarily for protection against chemical and/or mechanical effects. In a measuring environment in which such protection is not necessary, the level measuring instrument may also be used without the insert 19.

Arranged directly on the antenna 9 is the microwave generator 13 for generating microwaves. The microwave generator 13 is, by way of example, a pulsed radar instrument designed using planar circuitry, an FMCW instrument designed using planar circuitry or a continuously oscillating microwave oscillator designed using planar circuitry, e.g. a Gunn oscillator. It is located on a board 21 projecting into the hollow waveguide 15 and is connected directly to a transmission and reception element 23 pointing into the antenna 9.

Other electronic circuit elements (not shown in FIG. 2) suitable for picking up, converting and processing microwave signals, e.g. filters, directional couplers, mixers and the like, may be arranged on the board 21. These components can likewise be produced using planar circuitry. If the antenna 9 is used for transmitting and receiving, then a directional coupler needs to be provided, for example, via which microwaves from the microwave generator 13 reach the transmission and reception element 23, and microwaves received by the transmission and reception element 23 reach a unit which processes the echo signals further.

The transmission and reception element 23 is an extension of the connection between microwave generator 13 and the transmission and reception element 23. The board 21 has a section 25 which is inserted laterally into the antenna 9 through a recess 27 in the hollow waveguide 15. The section 25 is arranged parallel to the back wall 13 and at a distance therefrom, and the transmission and reception element 23 is arranged on the section 25.

At least one microstrip line arranged on the section 25 serves as connection and as transmission and reception element 23. A microwave-radiating surface of the microstrip line points in the transmission direction in the exemplary embodiment shown. Other orientations of the radiating surface, e.g. in the direction of the back wall 13, are also possible in principle.

The microwave generator 13 is connected directly, in particular without interposition of a supply line which is to be connected to the two ends thereof, to the microstrip line and hence to the transmission and reception element 23 formed thereby.

FIG. 3 shows a plan view of a side of the board 21 from FIG. 2 which points in the transmission direction, and FIG. 4 shows a plan view of a side of the board 21 from FIG. 2 which faces away from the transmission direction.

As can be seen from FIG. 3 and FIG. 4, the transmission and reception element 23 in the exemplary embodiment shown comprises a microstrip line 27 which is straight. It runs on a face of the section 25 of the board 21 which points in the transmission direction, and ends inside the hollow waveguide 15.

To improve the transmission properties, an electrically conductive body 29 pointing in the transmission direction is fitted to the end of the microstrip line inside the hollow waveguide 15.

Boards with microstrip lines usually have, on their surface opposite the surface which has the line structure, an electrically conductive coating which is connected to ground or to another reference-ground potential. As FIG. 4 shows, the board 21 likewise has a coating 31 which is connected to a reference-ground potential U. Simulation calculations and experiments have shown, however, that the transmission power is improved if at least the section 25 situated in the hollow waveguide 15 is free of coating.

For the purposes of level measurement, the geometry of the transmission and reception element 23 is preferably designed to excite the transverse-electric 11 mode (TE-11) capable of propagation in round hollow waveguides. This mode has a radiation characteristic with a pronounced forward lobe and is therefore particularly suitable for directional transmission of microwaves. Simulation calculations can then be used to optimize the dimensions of hollow waveguide and microstrip lines for a desired frequency. In the case of microwave signals which have a frequency spectrum with a bandwidth, the basis used for optimization may be a center frequency or a frequency possessed by a fundamental component of the microwave power which is to be transmitted.

However, the invention is limited neither to round hollow waveguides nor to the TE-11 mode, but instead may also be used in a similar manner for other hollow waveguide cross sections, e.g. rectangular hollow waveguides, and other propagation modes.

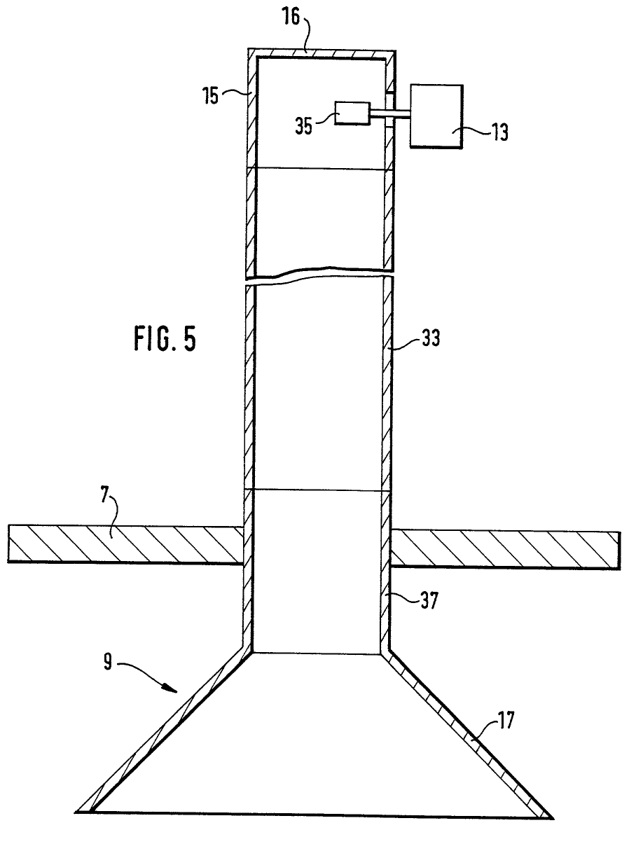

In some applications, it is not possible to fit the microwave generator directly on the antenna, for example on account of temperatures which may arise in the surroundings of the antenna 9. In such cases, there is the option of generating the microwaves away from the antenna and of routing them to the antenna 9 using a passive waveguide. An exemplary embodiment in which the microwave generator 13 is connected to the antenna 9 by means of a passive waveguide 33 is shown schematically in FIG. 5.

In exactly the same way as in the exemplary embodiment shown in FIG. 1, the level measuring instrument has a hollow waveguide 15 short-circuited at the end by a back wall 16. This hollow waveguide 15 is at a distance from the section of the antenna 9 which is inserted into the container 3. Inserted into the hollow waveguide, close to the back wall 16 and at a distance therefrom, is a transmission and reception element 35, e.g. a mushroom-shaped metal pin, which is connected directly to the microwave generator 13.

In the exemplary embodiment shown, the passive waveguide 33 is a hollow waveguide, in this case a round hollow waveguide, which runs from the hollow waveguide 15 to the container 3. In exactly the same way as in the exemplary embodiment shown in FIG. 1, a horn antenna is routed into the container 3. The horn antenna has a funnel-shaped horn 17 and a cylindrical section 37 which is integrally formed thereon, is routed out of the container 3 and forms a hollow waveguide. The cylindrical section 37 forms a continuation of the passive waveguide 33 and has a flange which is integrally formed thereon, extends radially outward and is used to mount at least that section of the level measuring instrument 5 which projects into the container 3 on the container 3. Depending on the length of the passive waveguide 33, a further fastening apparatus may be necessary further away from the container 3, e.g. in the region of the hollow waveguide 15, in order to fasten the hollow waveguide 15 and, by way of example, a housing (not shown in FIG. 5) enclosing the microwave generator 13 and the reception and evaluation circuit 15.

Other forms of passive waveguides suitable for transporting microwaves at frequencies of greater than 40 GHz may likewise be used, of course. Thus, by way of example, instead of the hollow waveguide shown in FIG. 5, which represents a direct extension of the hollow waveguide 15, leading to the hollow waveguide 37, other hollow waveguide geometries may also be used. Thus, for example using appropriate transition elements which effect impedance matching and/or mode conversion, e.g. funnels or transition elements whose cross sections change continuously, hollow waveguide segments with other cross section shapes or other diameters can be used for routing microwaves.

FIG. 6 shows a block diagram of a level measuring instrument, operating on the basis of the pulsed radar method, in which a single antenna 9 is used for transmitting and for receiving microwaves.

The core part of the block diagram is a microwave generator 13 which continuously generates microwaves at a frequency of greater than 40 GHz. A generator 41 oscillating at a pulse repetition rate is provided which is connected to a control circuit 43. The control circuit 43 starts the microwave generator 13 for a very short interval of time which corresponds to the desired pulse duration of the microwave pulses which are to be transmitted, and then stops it again. This procedure is repeated at the pulse repetition rate present on the control circuit 43. This is a few megahertz, for example. The microwave generator 13 is connected to the antenna 9 via a directional coupler or circulator 45. In addition, the microwave generator 13 and the antenna 9 may have a filter 44 provided between them which serves to filter out undesirable frequencies or other signal components, such as may arise as a result of the control circuit 43.

Microwaves transmitted via the antenna 9 are reflected at the filled product surface and are received by the antenna 9 again after a level-dependent transit time. Received microwaves are supplied to the reception and evaluation circuit 15 via the directional coupler or circulator 45. The reception and evaluation circuit 15 comprises a low-noise, linear amplifier 47 at the input. The microwaves received are amplified and are supplied to a first input of a mixer 49.

The generator 41 oscillating at the pulse repetition rate is connected to a second microwave generator 54 via a time delay stage 51 and a second control circuit 53, operating in an identical manner to the first control circuit 43. The second microwave generator 54 is of identical design to the first microwave generator 13. The control circuit 53 causes the second microwave generator 54 to generate microwave pulses repeatedly at the pulse repetition rate. These microwave pulses are applied to a second input of the mixer 49. The time delay stage 51 delays the entering signals by a variable delay time, for example rising in accordance with a sawtooth function of finite width. The mixer 49 thus superimposes on a microwave signal delayed by a level-dependent transit time a microwave signal which has fundamentally the same shape and is delayed by a variable delay time. The signal available at the output of the mixer 49 corresponds to the correlation of the microwave signals entering at the two inputs thereof. It contains a high-frequency component, which contains frequencies which are essentially provided by the sum of the frequencies applied to the inputs, and a low-frequency component, which contains frequencies which are essentially provided by the difference between the frequencies applied to the inputs. The low-frequency component is filtered out using a low-pass filter 55 and is supplied to further processing and/or evaluation via a further amplifier 57. The output signal can, by way of example, be recorded using a sample and hold circuit (not shown in FIG. 6), and the respective signal amplitude can be recorded together with the associated delay time. A maximum signal amplitude, that is to say a maximum correlation between the microwave signals present on the mixer 49, always arises whenever the delay time corresponds to the level-dependent transit time. Hence, the level-dependent transit time can be calculated. If the installation height of the antenna 9 and the dimensions of the container 3 are known, the present level is given directly by this.

FIG. 7 shows a block diagram of an inventive level measuring instrument whose manner of operation is identical to the block diagram shown in FIG. 6. However, a first antenna 9a, which is used exclusively for transmission, and a second antenna 9b, which is used exclusively for reception, are provided. Accordingly, the first antenna 9a is connected to the microwave generator 13. The generator 41 which is connected upstream of the microwave generator 13 and oscillates at the pulse repetition rate and the control circuit 43 repeatedly transmit short microwave pulses at the pulse repetition rate, in exactly the same way as in the exemplary embodiment shown in FIG. 6. In this case too, the filter 44 can be provided between the microwave generator 13 and the first antenna 9a. The reflected microwaves are received by the antenna 9b and are supplied to the first input of the mixer 49 via the amplifier 47.

In this case too, the generator 41 is connected to the second microwave generator 54, which is of identical design to the first microwave generator 13, via the time delay stage 51 and the control circuit 53. The short microwave pulses output by the second microwave generator 54 are applied to the second input of the mixer 49. The further processing of the output signals from the mixer 49 tallies with the processing described previously in connection with the exemplary embodiment shown in FIG. 6.

What we claim is:

1. A level measuring instrument operating with microwaves in order to measure a level of a filled product (11) in a container (3), having
a microwave generator (13),
for producing microwaves at frequencies of greater than 40 GHz,
an antenna (9, 9a) which is powered by the microwave generator (13) and is used to transmit the microwaves in the direction of the filled product,
an antenna (9, 9b) which is used to receive microwaves reflected at a filled product surface, and
a reception and evaluation circuit (15)
which ascertains a transit time for the microwaves and uses this to determine the present level.

2. The level measuring instrument operating with microwaves as claimed in claim 1, in which the microwave generator (13) is arranged directly on the antenna (9, 9a).

3. The level measuring instrument operating with microwaves as claimed in claim 1, in which the microwave generator (13) is connected to the antenna (9) by means of a passive waveguide (33).

4. The level measuring instrument operating with microwaves as claimed in claim 3, in which the passive waveguide (33) is a hollow waveguide.

5. The level measuring instrument operating with microwaves as claimed in claim 1, in which a product comprising an aperture of the antenna and a wavelength of the microwaves is much less than 500 mm².

6. The level measuring instrument operating with microwaves as claimed in claim 1, in which the filled product (11) is a bulk product, and in which the wavelength of the microwaves is in the order of magnitude of a mean particle size of the bulk product or is less than this particle size.
